(19) United States
(12) Patent Application Publication
(10) Pub. No.: US 2024/0351113 A1
(43) Pub. Date: Oct. 24, 2024

(54) COATED CUTTING TOOL

(71) Applicant: WALTER AG, Tubingen (DE)

(72) Inventors: Thorsten MANNS, Tubingen (DE); Wiebeke JANSSEN, Tubingen (DE)

(21) Appl. No.: 18/574,999

(22) PCT Filed: Jun. 30, 2022
(86) PCT No.: PCT/EP2022/068049

§ 371 Date: Dec. 28, 2023

(30) Foreign Application Priority Data
Jul. 2, 2021 (EP) 21183417.1

(51) Int. Cl. B23B 27/14; C23C 16/02; C23C 16/36; C23C 16/40; C23C 16/56

(52) U.S. Cl. CPC B23B 27/14; C23C 16/0272; C23C 16/36; C23C 16/403; C23C 16/56

(57) ABSTRACT

A coated cutting tool consisting of a substrate and a multi-layered wear resistant hard coating and a process for manufacturing the same is provided. The layers of the hard coating are deposited by chemical vapour deposition (CVD) and include a TiCN layer with a multi-sublayer structure of alternating C-type and N-type sublayers and an overall fiber texture characterized by a texture coefficient TC (4 2 2) in the range from 3.0 to 5.5, an oxygen containing Ti or Ti+Al compound bonding layer, and an α-Al₂O₃ layer on top of the bonding layer with an overall fiber texture characterized by a texture coefficient TC (0 0 12)>5.

### FIELD OF THE INVENTION

The present invention relates to a coated cutting tool for chip-forming metal machining consisting of a substrate and a multi-layered wear resistant hard coating, the layers of the hard coating being deposited by chemical vapour deposition (CVD).

### BACKGROUND OF THE INVENTION

Common cutting tools used in metal machining consist of a base body of cemented carbide, cermet, ceramics, steel or cubic boron nitride or the like and a single-layer or a multi-layer wear resistant hard material coating deposited by CVD or PVD. Specifically, one type of high performance cutting tools comprise a base body (substrate) of cemented carbide, a thin base layer of TiC or TiN, a layer of TiCN, in most cases deposited as a MT-TiCN (moderate temperature CVD), followed by an alpha, kappa or mixed alpha+kappa Al₂O₃ layer. It is also known to provide a Ti compound or Ti+Al compound bonding layer between the TiCN layer and the Al₂O₃ layer, which bonding layer may be suitable to convey crystallographic properties from the underlying TiCN layer into the Al₂O₃ layer, and may have influence on the modification, texture and adherence of the Al₂O₃ layer. For example, a certain degree of oxidation at the surface of the Ti or Ti+Al compound bonding layer may promote the formation of alpha Al₂O₃ over the kappa modification. An example can be found in U.S. Pat. No. 7,172,807.

The performance and lifetime of such cutting tools is influenced by various parameters. Some parameters are more or less given due to the desired machining application, such as the work piece material, the intended cutting operation, etc. However, there is still potential for the improvement of the cutting tool itself, especially with respect to the coating properties and the balance between different parts and layers of the coating to influence different wear types and increase tool life and cutting performance.

### OBJECT OF THE INVENTION

It is an object of the present invention to provide a coated cutting tool having improved wear and oxidation resistance as well as enhanced edge line toughness in continuous and interrupted cutting, especially for ISO P and ISO K steel applications.

### DESCRIPTION OF THE INVENTION

This object has been solved by a coated cutting tool for chip-forming metal machining consisting of a substrate and a multi-layered wear resistant hard coating, comprising:
a) a TiCN layer having a total thickness of from 2 μm to 20 μm,
   wherein the TiCN layer has a multi-sublayer structure of a total of p alternating C-type and N-type sublayers with p being an even or odd number in the range from 5 to 25, preferably from 5 to 12,
   wherein the C-type and N-type sublayers have different stoichiometries with respect to the atomic ratio of carbon and nitrogen, with the C-type TiCN sublayers having a C/N ratio in the range of 1.0≤C/N≤2.0, and the N-type TiCN sublayers having a C/N ratio in the range of 0.5≤C/N<1.0, and with the difference between the C/N ratio of adjacent C-type and N-type layers being ≥0.2, and
   wherein the TiCN layer has an overall fiber texture characterized by a texture coefficient TC (4 2 2) in the range from 3.0 to 5.5, the TC (4 2 2) being defined as follows:

$$T C ( 422 ) = \frac{I ( 422 )}{{I}_{0} ( 422 )} \cdot {( \frac{1}{n} \cdot {\sum }_{1}^{n} \frac{I ( hkl )}{{I}_{0} ( h k l )} )}^{- 1}$$

wherein
   I(h k l)=XRD intensity of the (h k l) reflection
   I₀(h k l)=standard intensity of the standard powder diffraction data according to lCDD's PDF-card no 01-071-6059
   n=7=number of reflections used in the calculation, whereby the seven (h k l) reflections used are: (1 1 1), (2 0 0), (2 2 0), (3 1 1), (3 3 1), (4 2 0), and (4 2 2),
b) a single-layer or multi-sublayer oxygen containing Ti or Ti+Al compound bonding layer on top of the TiCN layer with a total thickness of from 0.5 μm to 3 μm,
c) an α-Al₂O₃ layer on top of the bonding layer with a total thickness of from 2 μm to 15 μm,
   wherein the α-Al₂O₃ layer has an overall fiber texture characterized by a texture coefficient TC (0 0 12) >5, the TC (0 0 12) being defined as follows:

$$TC ( 0 \; 012 ) = \frac{I ( 0012 )}{{I}_{0} ( 0012 )} \cdot {( \frac{1}{n} \cdot {\sum }_{1}^{n} \frac{I ( hkl )}{{I}_{0} ( h k l )} )}^{- 1}$$

wherein
   I(h k l)=XRD intensity of the (h k l) reflection
   I₀(h k l)=standard intensity measured on the NIST standard powder SRM676a
   n=8=number of reflections used in the calculation, whereby the eight (h k l) reflections used are: (1 0 4), (1 1 0), (1 1 3), (0 2 4), (1 1 6), (3 0 0), (0 0 12) and (0 1 14),
   the standard intensities having the following values:

| | {h k l} | | | | | | | |
|---|---|---|---|---|---|---|---|---|
| | {1 0 4} | {1 1 0} | {1 1 3} | {0 2 4} | {1 1 6} | {3 0 0} | {0 0 12} | {0 1 14} |
| I₀ (h k l) | 87.93 | 37.68 | 100.00 | 45.76 | 92.43 | 53.93 | 2.05 | 5.16 |

In the following herein, the terms “{2 1 1} texture of the TiCN layer” and “{0 0 1} texture of the α-Al₂O₃ layer” mean preferred crystallographic orientations in the polycrystalline layers with the respective crystallographic planes being orientated parallel to the substrate surface (perpendicular to the growth direction of the layers) more frequently than in random orientation. The preferred crystallographic orientations are herein determined by XRD and expressed by the texture coefficients of the corresponding (parallel) crystallographic {4 2 2} and {0 0 12} planes, respectively, TC (4 2 2) of the TiCN layer, and TC (0 0 12) of the α-Al₂O₃ layer.

Attempts to improve the properties and performance of cutting tools have to take into account several aspects, at the same time. It was found that control of a high {0 0 1} texture of the α-Al₂O₃ layer, expressed by a texture coefficient TC(0 0 12)>5, is a key for high oxidation resistance and crater wear resistance. Preferably, the texture coefficient TC(0 0 12) of the α-Al₂O₃ layer is >6. On the other hand, flank wear resistance was found to be strongly influenced by the microstructure and texture of the TiCN layer in the coating layer sequence. Another essential feature for cutting tool performance and tool life is edge line toughness, which, however, can be limited by the adhesion of the coating layers at the layer interfaces. Low adhesion leads to breaking, chipping and/or peel-off, and thus, to early failure of the tool. By the specific coating sequence and the properties of each of the coating layers the inventors have found a new coated cutting tool that provides improved edge line toughness and flank wear as well as improved oxidation and crater wear resistance.

In the best mode of the inventive coated cutting tool the layers of the hard coating are deposited by chemical vapour deposition (CVD), and the TiCN layer with the multi-sublayer structure is a MT-TiCN layer deposited by MT-CVD at a reaction temperature in the range from 600° C. to 900° C. The polycrystalline TiCN layer consists of columnar grains.

The Ti or Ti+Al compound bonding layer is preferably deposited by HT-CVD at a reaction temperature in the range from 900° C. to 1200° C., and the α-Al₂O₃ layer is preferably also deposited by HT-CVD at a reaction temperature in the range from 900° C. to 1200° C.

It was known that a certain degree of oxidation state in the Ti or Ti+Al compound layer underneath the Al₂O₃ layer promotes nucleation and subsequent growth of the alpha-modification over other modifications. However, it has been found that the development and level of texture of the α-Al₂O₃ layer is determined not only by the deposition conditions of the Al₂O₃ layer as such, but to a certain degree also by the microstructure and crystallographic orientation of the underlying TiCN layer. Therefore, control of the TiCN layer is also essential to control the properties of the subsequent α-Al₂O₃ layer.

The inventors have recognized that a fine grained TiCN layer with a high {211} texture promotes the controlled nucleation and deposition of a highly {001} textured α-Al₂O₃ layer and high flank wear resistance of the coating. Thus, in a first attempt, an as high as possible {211} texture of the TiCN layer would be assumed to improve the advantageous properties resulting from a highly {001} textured α-Al₂O₃ layer and flank wear resistance.

However, it was further found by the inventors by numerous experiments and analyses that the adhesion especially at the interface between the α-Al₂O₃ layer and the underlying bonding layer of the coating is strongly influenced by the microstructure and crystallographic orientation of the TiCN layer. A high {211} texture of the TiCN layer, which promotes the advantages of a highly {001} textured α-Al₂O₃ layer and high flank wear resistance, was found to be often coupled to a very weak adhesion at the interface between the α-Al₂O₃ layer and the bonding layer resulting in breaking and chipping especially at the edge line of the tool, and thus, in impaired tool performance and tool life.

This contradiction could be solved by the present invention by a multi-layered wear resistant hard coating as herein defined, wherein the TiCN layer has a multi-sublayer structure of a specific number of from 5 to 25 alternating C-type and N-type sublayers of well-defined C/N ratios and wherein the TiCN layer has a {211} texture, expressed by the texture coefficient TC(4 2 2), within a specified range from 3.0 to 5.5. Preferably, the texture coefficient TC(4 2 2) is from 3.5 to 5.5, or from 4.0 to 5.3.

On one hand, the texture coefficient TC (4 2 2) of the TiCN layer is sufficiently high to promote the growth and advantageous properties of the subsequent α-Al₂O₃ layer. On the other hand, the limitation of the texture coefficient TC (4 2 2) of the TiCN layer was found to reduce or avoid adhesion problems between the α-Al₂O₃ layer and the bonding layer.

To achieve these properties, it has been found advantageous to deposit a multi-sublayered TiCN layer, which mainly consists of C-type TiCN, wherein the growth of C-type TiCN is regularly interrupted by the deposition of N-type TiCN sublayers. It is assumed and has been found that the interruption of the C-type TiCN growth conditions by a sublayer of N-type TiCN controls the {211} texture of the TiCN layer, herein expressed by the texture coefficient TC (4 2 2).

Whereas the C-type TiCN promotes the {211} texture of the TiCN layer, the type and number of N-type TiCN sublayers are suitable to control and adjust the limits of the {211} texture of the TiCN layer. Deposition of an N-type layer mono-layer alone has turned out to go along with disadvantages, such as randomly textured crystals and/or very coarse grains.

It has been shown that best properties of the TiCN layer and control of the {211} texture is achieved, if the N-type sublayers are thin compared to the adjacent C-type sublayers in the multi-sublayer structure of the TiCN layer. Preferably, each N-type sublayer has a thickness of less than 50%, or less than 40%, or less than 30% of each of the adjacent C-type sublayers. On the other hand, each N-type sublayer should have a thickness of at least 0.05 μm, or at least 0.1 μm, or at least 0.2 μm. Otherwise the effect of the N-type sublayers to control the texture of the TiCN multi-layer would be too low.

The changes between C-type and N-type sublayers during deposition of the TiCN layer are controlled by changes of the deposition conditions, especially the reaction gas compositions. The thicknesses of the C-type and N-type sublayers are controlled by the deposition times under the respective C-type and N-type conditions. It should be mentioned that the deposition rates under different C-type and N-type conditions must not necessarily be the same, however, it is within the artisan's skill to find the respective deposition rates under certain conditions by simple experimentation.

It has also been found that the number of alternating C-type and N-type sublayers must not be too low or too high to achieve the desired properties of the TiCN layer. A number of 5 to 25 alternating C-type and N-type sublayers has turned out to be advantageous to control the {211} texture of the TiCN layer within the beneficial texture coefficient TC (4 2 2) range.

According to the present invention, the C-type TiCN sublayers have a C/N ratio in the range of 1.0≤C/N≤2.0, and the N-type TiCN sublayers have a C/N ratio in the range of 0.5≤C/N<1.0. In an embodiment of the invention the C-type TiCN sublayers have a C/N ratio in the range of 1.2≤C/N<1.5, and the N-type TiCN sublayers have a C/N ratio in the range of 0.7<C/N<1.0. The effect of the interruption of the growth of C-type TiCN by the deposition of alternating N-type TiCN sublayers can be influenced not only by the number of C-type interrupting N-type sublayers, but also by adjustment of the C/N ratios and the difference of the C/N ratios between C-type and N-type sublayers. In the deposition process, the C/N ratios in the deposited layers are adjusted by the deposition conditions, mainly by the ratio of N-donor and C-donor. In the reaction gas system with N₂ and CH₃CN as N and C sources, the C/N ratio is adjusted by the ratio of these precursor gases.

According to the present invention, the difference between the C/N ratios of adjacent C-type and N-type layers is ≥0.2. In a preferred embodiment of the present invention the difference between C/N ratios of the C-type and N-type layers is within the range from 0.3 to 1.5, or from 0.4 to 1.0, or from 0.5 to 0.8. If the difference between the C/N ratios of adjacent C-type and N-type layers is too low, the desired effect to control the crystallographic properties of the TiCN layer is too weak.

The substrate of the inventive coated cutting tool may be of any type known in the art to be suitable for metal cutting tools, such as cemented carbide, cermet, ceramics, steel or cubic boron nitride, whereby cemented carbide is particularly suitable and preferred.

It has turned out that the coated cutting tool of the present invention exhibits superior wear and oxidation resistance as well as enhanced edge line toughness in continuous and interrupted cutting, especially in turning operations for ISO-P and ISO K steel workpiece applications. Therefore, the present invention includes the use of the inventive coated cutting tool for continuous and interrupted cutting of ISO-P and ISO K steel materials.

In a preferred embodiment of the inventive coated cutting tool, at least one base layer of TiN or TiC is deposited immediately on the substrate surface and underneath the TiCN layer. A suitable base layer has a thickness in the range from 0.3 to 1.5 μm, or from 0.3 to 1.0 μm, or from 0.3 to 0.7 μm. The base layer may be deposited by thermal HT-CVD or MT-CVD.

The base layer is suitable to improve the adhesion of the TiCN layer to the substrate. The base layer may also serve as a barrier layer to avoid or at least lower diffusion of components, such as Co, from the substrate into the TiCN coating layer and vice versa during subsequent high temperature treatment, such as during the HT-CVD alumina deposition.

In a preferred embodiment of the inventive coated cutting tool in the multi-sublayer structure of the TiCN layer in the growth direction the first sublayer on top of the base layer is a C-type layer. In another preferred embodiment both the first sublayer on top of the base layer and the final sublayer underneath the bonding layer are C-type layers.

As stated above, the major proportion of the multi-layered TiCN layer is C-type TiCN, which has turned out to be the type promoting the {211} texture of the TiCN layer, which in turn promotes the {001} texture of the α-Al₂O₃ layer, whereas the N-type sublayers are preferably interposed to control the {211} texture development of the TiCN layer. However, if a N-type layer is deposited as the first sublayer on top of the base layer, the development of {211} texture of the TiCN layer was found to be low, and as a consequence the {001} texture of the α-Al₂O₃ layer was lower. The effect can even be increased and better control of the {001} texture of the α-Al₂O₃ layer is achieved, if also the final sublayer underneath the bonding layer is a C-type layer.

There are two preferred variants of the inventive coated cutting tool with respect to the multi-sublayer structure of the TiCN layer.

In a first variant, the first C-type sublayer in the growth direction is comparatively thick having a thickness in the range from 5 to 15 μm, and the subsequent C-type sublayers are thinner having a thickness in the range from 0.5 to 4 μm, with the even thinner N-type sublayers being deposited between the C-type layers. In this variant, in first stage, the first thicker C-type sublayer develops a pronounced {211} texture and sets a kind of template for the subsequent layers.

In a second variant, each C-type sublayer in the growth direction has a thickness in the range from 0.5 to 4 μm, with the even thinner N-type sublayers being deposited between the C-type layers. This variant also works very well, and is especially suitable if the number of alternating C-type and N-type sublayers in the TiCN layer is in the upper range and the total thickness of the TiCN layer should not become too high.

The bonding layer of the inventive coating is a single-layer or multi-sublayer oxygen containing Ti or Ti+Al compound layer deposited on top of the TiCN layer with a total thickness of from 0.5 μm to 3 μm. Preferably the bonding layer has a multi-sublayer structure and a total composition of TiCNO or TiAICNO. In the CVD deposition of the bonding layer, oxygen may be introduced by adding carbon monoxide, CO, to the reaction gas composition. In a preferred embodiment, the deposited bonding layer is additionally subjected to an oxidation step prior to the nucleation and growth of the subsequent Al₂O₃ layer. The presence of oxygen within the Ti or Ti+Al bonding layer and the oxidation of the bonding layer surface are suitable to promote the growth of the Al₂O₃ layer in the α-modification.

The present invention also includes the process for manufacturing of the inventive coated cutting tool as defined herein, wherein the multi-layered wear resistant hard coating is deposited on the a substrate by chemical vapour deposition (CVD), comprising the steps of:
deposition of the TiCN layer in a multi-sublayer structure of a total of p alternating C-type and N-type sublayers with p being an even or odd number in the range from 5 to 20, by MT-CVD at a reaction temperature in the range from 600° C. to 900° C. from a process gas composition comprising at least TiCl₄, H₂, N₂ and CH₃CN and optionally HCl, to a total thickness of from 2 μm to 20 μm,
wherein the C-type and N-type sublayers have different stoichiometries with respect to the atomic ratio of carbon and nitrogen, with the C-type TiCN sublayers having a C/N ratio in the range of 1.0≤C/N≤2.0, and the N-type TiCN sublayers having a C/N ratio in the range of 0.5≤C/N<1.0, and with the difference between the C/N ratio of adjacent C-type and N-type layers being ≥0.2, the C/N ratio being adjusted by the ratio of N₂/CH₃CN in the process gas composition,
deposition of the single-layer or multi-sublayer oxygen containing Ti or Ti+Al compound bonding layer on top of the TiCN layer to a total thickness of from 0.5 μm to 3 μm, by thermal HT-CVD or MT-CVD from a process gas composition comprising at least TiCl₄, H₂, N₂, CO and, if Al is present, AlCl₃ and optionally CH₄ and/or HCl,
carrying out an oxidation step to the bonding layer at a temperature in the range from 900-1200° C., a pressure in the range from 30 to 150 mbar, a time from 2-20 min, and in a gas atmosphere comprising or consisting of H₂, N₂, 1-10 vol. % CO₂ and 1-20 vol. % CO,
deposition of an α-Al₂O₃ layer on top of the oxidation step treated bonding layer with a total thickness of from 2 μm to 15 μm, by HT-CVD at a reaction temperature in the range from 900° C. to 1200° C.

Preferably, the process includes the further step of depositing at least one base layer of TiN or TiC immediately on the substrate surface to a base layer thickness in the range from 0.3 to 1.5 μm by thermal HT-CVD or MT-CVD from a process gas composition comprising at least TiCl₄, H₂ and N₂.

The Ti or Ti+Al compound bonding layer is preferably deposited by multiple subsequent deposition steps to obtain a multi-sublayer structure, wherein each deposition step is carried out by HT-CVD at a reaction temperature in the range from 900° C. to 1200° C. In the examples herein, the bonding layer is deposited in a five-step process, starting with a TiCN sublayer, followed by several steps under process conditions including CO in the reaction gas to incorporate oxygen into the layer, and steps including AlCl₃ to incorporate Al into the layer. The total (overall) composition of the bonding layer is Ti+Al+C+N+O. The deposition of the bonding layer is followed by an oxidation step at high temperature in the range from 900° C. to 1200° C., preferably about 1000° C., in a gas atmosphere containing H₂, N₂, CO₂ and CO.

### BRIEF DESCRIPTION OF THE FIGURES

FIG. 1 shows examples of light optical micrographs (LOM) of polished calotte ground surfaces of coatings of different A adhesion classifications (FIG. 1a: A=1; FIG. 1b: A=2; FIG. 1c: A=3).

FIG. 2: shows average values for A and Z adhesion of inventive and comparative examples of coated cutting tool samples plotted over the number of sublayers in the TiCN layer (FIG. 2a) and plotted over the texture coefficient TC (4 2 2) of the TiCN layer (FIG. 2b), respectively.

FIG. 3 shows light optical photographs of crater wear of inventive samples (FIG. 3a, 3b: 4WAG51; FIG. 3c, 3d: 4WAG60) and a reference sample (FIG. 3e, 3f: 1246260) after the crater wear test (turning operation in C45E steel) for 12 min cutting time (FIG. 3a, 3c, 3e) and 15 minutes cutting time (FIG. 3b, 3d, 3f).

FIG. 4 shows the flank wear of the samples 4WAG51, 4WAG60 and reference 1246260 shown in FIG. 3 after each cycle of 3 min in the crater wear test.

FIG. 5: shows the flank wear of inventive samples 4WAG51 and 4WAG55 and reference sample 1246260 in the toughness test, wherein the maximum wear width is plotted over the number of cycles, with the edge line damage (ELD) being indicated for each sample at the end of tool life (VBₘₐₓ on the flank face 0.3 mm).

FIG. 6 shows an example of a TEM (FIG. 5a) and an EDXS line scan (FIG. 5b) along line A-B in layer growth direction on a sample of an inventive TiCN layer. In the TEM representation the thicker C-type sublayers (bright) are interrupted by six thin N-type sublayers (dark). The EDXS line scan shows the concentrations of Ti, C and N in at-% over the length of about 4 μm of the line A-B. In this sample, the average C/N ratio of the C-type sublayers was about 1.42, and the average C/N ratio of the n-type sublayers was about 0.85, determined by EDXS. The C/N ratio results could be confirmed by EELS line scan.

### DEFINITIONS AND METHODS

### MT-TiCN

The term “MT-TICN”, as it is used herein, implies that TiCN is deposited by moderate temperature CVD (MT-CVD), which distinguishes the material being deposited by high temperature CVD (HT-CVD).

### X-Ray Diffraction (XRD) Measurements

X-ray diffraction measurements were performed on a Panalytical CubiX3 diffractometer using CuKα-radiation and a PIXcel 1D RTMS detector. The X-ray tube was run in line focus at 45 kV and 40 mA. Measurements were done in Bragg-Brentano geometry. On primary beam side a Soller slit of 0.04 rad, a fixed divergence slit of 0.5° and an anti-scatter slit of 1° were used. To avoid a spill over of the X-ray beam over the coated face of the sample a beam mask of 1.6 mm width was inserted. On the secondary side a fixed anti-scatter slit of 8 mm, a Soller slit of 0.04 rad and a 20 μm thick NiKβ filter were used. Symmetrical θ-2θ scans within the angle range of 19°≤2θ≤130° with increments of 0.0158° and approximately 0.2 second counting time have been conducted.

The data analysis was done using a Matlab based peak fitting procedure by fitting Pseudo-Voigt profiles to the measured 20 scans after Cu-Kα₂ stripping (Rachinger method) and background subtraction has been performed. Peak intensities herein are peak area intensities. Correction for thin film absorption (TF) was applied to all samples, which takes into account the limited thickness of the layer in contrast to the natural penetration depth in a bulk material. Furthermore, absorption correction (Abs) was applied for layers deposited above the respective layer of interest. The equations applied for thin film (TF) correction and absorption (Abs) correction are known to the skilled person and are shown below:

$${I}_{corr}^{T F} = \frac{{I}_{0}}{1 - exp ( - 2 μ S / sin θ )} \qquad {I}_{corr}^{A b s} = \frac{{I}_{0}}{exp ( - 2 μ S / sin θ )}$$

In the equation for thin film correction (I^{TF}_{corr}), S is the thickness of the layer of interest, and in the equation for absorption correction (I^{Abs}_{corr}), S is the thickness of an absorbing top layer, respectively. “μ” is the linear absorption coefficient of the respective layer material with μ(α-Al₂O₃)=0.01258 μm⁻¹ and p(TiCN)=0.08150 μm⁻¹. (See also: Birkholz, Thin Film Analysis by X-ray Scattering, 2006, Wiley-VCH, ISBN 3-527-31052-5, chapter 5.5.3, pages 211-215).

Since the bonding layer is thin, has the same crystal structure and similar chemical composition compared to the TiCN coating, the superposed interference peaks of both layers cannot be separated or trustworthy deconvoluted. Therefore, no separate absorption correction and thin film correction, respectively, was made for the bonding layer overlaying the TiCN coating. Instead they are treated as one layer.

### Texture Coefficient TC(h k l)

The term “fiber texture”, as it is generally used in connection with polycrystalline thin films produced by vapor deposition, describes a preferential crystallographic orientation of the grown grains compared to random orientation, in that a set of geometrically equivalent crystallographic planes {h k l} is found to be preferentially oriented parallel to the substrate surface.

A means to express preferred growth, i.e. that one set of geometrically equivalent crystallographic planes {h k l} is found to be preferentially oriented parallel to the substrate, is the texture coefficient TC(h k l) calculated using the formalism proposed by Harris on the basis of a defined set of XRD reflections measured on the respective sample (Harris, G. B., Philosophical Magazine Series 7, 43/336, 1952, pp. 113-123). According to the Harris formula, the measured peak intensities I(h k l) are correlated to the relative standard intensities I₀(h k l) taken from the respective lCDD's PDF-card or measured on a standard reference powder.

$$T C ( h k l ) = \frac{I ( hkl )}{{I}_{0} ( h k l )} \cdot {( \frac{1}{n} \cdot {\sum }_{1}^{n} \frac{I ( hkl )}{{I}_{0} ( h k l )} )}^{- 1}$$

A texture coefficient TC(h k l)>1 of a layer of crystalline material is an indication that the grains of the crystalline material are oriented with their {h k l} crystallographic plane parallel to the substrate surface more frequently than in a random distribution, at least compared to the XRD reflections used in the Harris formula. For the calculation of texture coefficients TC(h k l) herein, the measured peak intensities I(h k l) mean the net peak area intensities corrected as described above.

For TiCN the lCDD's PDF-card no 01-071-6059 was applied, and the following (h k l) reflections were used in the calculation (n=7):

| | {h k l} | | | | | | |
|---|---|---|---|---|---|---|---|
| | {1 1 1} | {2 0 0} | {2 2 0} | {3 1 1} | {3 3 1} | {4 2 0} | {4 2 2} |
| Std. Intensity I₀ | 803 | 999 | 464 | 198 | 62 | 124 | 100 |

For α-Al₂O₃ the standard peak area intensities I₀(h k l) were obtained by measurement, as described above, on the certified NIST (National Institute of Standards and Technology) standard powder SRM676a. The following (h k l) reflections were used in the calculation (n=8):

| | {h k l} | | | | | | | |
|---|---|---|---|---|---|---|---|---|
| | {1 0 4} | {1 1 0} | {1 1 3} | {0 2 4} | {1 1 6} | {3 0 0} | {0 0 12} | {0 1 14} |
| Std. Intensity I₀ | 87.93 | 37.68 | 100.00 | 45.76 | 92.43 | 53.93 | 2.05 | 5.16 |

### Scanning Electron Microscopy (SEM)

For SEM analyses inserts were cut in cross section, mounted in a holder and then treated by i) grinding with Struers Piano220 disc with water for 6 min; ii) polishing with 9 μm MD-Largo Diamond suspension for 3 min; iii) polishing with 3 μm MD-Dac Diamond suspension for 3:40 min; iv) polishing with 1 μm MD-Nap Diamond suspension for 2 min; v) polishing/etching with OP-S colloidal silica suspension for at least 12 min (average grain size of the colloidal silica=0.04 μm). The specimens were ultrasonically cleaned before SEM examination. SEM images were acquired on a Zeiss Supra 40 VP field emission scanning electron microscope using a 30 μm aperture, 2.5 kV acceleration voltage and a working distance of 5 mm.

### Sample Preparation for TEM Analyses

The preparation of samples for TEM was made by the in-situ lift-out technique using a combined FIB/SEM equipment Zeiss Crossbeam 540 field emission scanning electron microscope equipped with a gallium liquid metal ion source to cut a thin cross sectional piece out of the surface and thin the sample down to sufficient electron transparency.

Analytical Transmission Electron Microscopy (TEM) investigations (STEM-EDXS) Combined scanning transmission electron microscopy (STEM) imaging and element mapping via energy-dispersive X-ray spectroscopy (EDXS) was performed on an FEI Tecnai Osiris microscope at 200 keV primary electron energy with an electron current of 1 nA, the microscope is equipped with a high-brightness field emission electron gun and four silicon-drift detectors (FEI Super-X EDX system).

STEM-EDXS mappings were used for the determination of the sublayer thicknesses of the C-type and the N-type layers respectively. The derived quantitative line profiles of the element distributions demonstrate a high homogeneity and reproducibility over the alternating C-type and N-type layer stack. C/N ratios were determined by line profile fitting using Matlab.

### Electron Energy Loss Spectroscopy (EELS)

Electron energy loss spectroscopy (EELS) was carried out by means of a Gatan imaging energy filter of the type GIF Tridiem 865 ER on an FEI Titan 80-300 microscope at 300 kV. EELS line-profile analyses were done in the STEM mode. For the accurate quantification of the C/N ratios EELS analyses with high spatial resolution were applied. These measurements confirm the data from the STEM EDXS analyses.

### Calotte Grinding/Ball Cratering

Calotte grinding was used to assess coating thickness and adhesion. The insert was placed on an inclined magnetic holder of the ball cratering set-up. A spherical calotte was ground in the coating and substrate material by a rotating 30 mm steel ball wetted with a drop of 3 μm water-based diamond suspension (Struers, DP-Lubricant Green) and driven by a driving shaft at >500 rpm. The grinding process was stopped when the calotte diameter in the substrate material reached approx. 600-1100 μm. The thickness measurements taking into account the geometry of the calottes were done by a dedicated software using light optical microscopy (LOM).

### A Adhesion and Z Adhesion

“A adhesion” defines the adhesion of the α-Al₂O₃ layer to the bonding layer and, “Z adhesion” defines internal adhesion within the bonding layer, i.e. between individual sublayers of the bonding layer. A and Z adhesion were assessed by LOM observation on polished calotte ground surfaces and visually classified on a scale from 1.0 (=perfect adhesion) to 3.0 (=no adhesion).

The criteria for A and Z adhesion at the interfaces of layers/sublayers are as follows:
A or Z=1: no or neglectable breakouts are observable at the interfaces, the interface line is intact.
A or Z=2: minor breakouts can be observed at the interface, about 51-80% of the total interface line are without deterioration.
A or Z=3: mayor breakouts or a continuous delamination are observable at the interface, 50-100% of the interface line in the calotte are deteriorated.

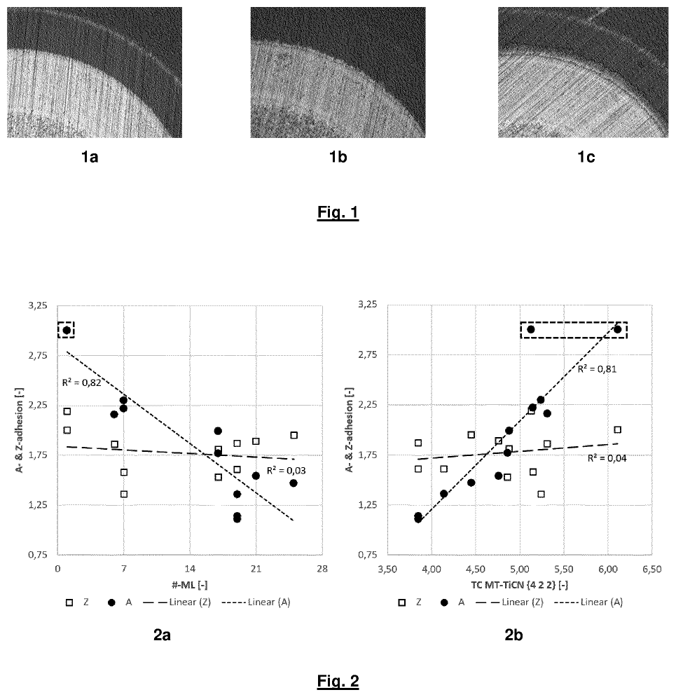

FIGS. 1a, 1b and 1c show examples of A adhesions (FIG. 1a: A=1; FIG. 1b: A=2; FIG. 1c: A=3).

### CVD Coatings

All CVD coatings herein were prepared in an industrial sized radial flow CVD coating chamber of type Bernex BPX530L with an inner reactor height of 1580 mm, an inner reactor diameter of 500 mm and an inner volume of approximately 300 litres. The reaction gas was fed into the reactor through a central gas inlet pipe and introduced into the reaction zone through openings distributed along the inlet pipe to provide an essentially radial gas flow over the substrate bodies.

It is noted that a high number of cutting tool insert substrates (in the order of up to about 15.000 inserts) may be placed in the reactor on the various tray levels and at different distances in radial direction from the reaction gas outlet openings. Accordingly, depending on the total gas flow, gas velocity and the type of deposition reaction, the reaction gas compositions, and thus, the reactivity at different substrate positions within the same reactor may vary and can result in varying coating thicknesses and other product parameters of the coated substrates within the same deposition run under the same nominal reaction conditions. This is a phenomenon well known to the skilled person. However, it is within the purview of the skilled person to lower or overcome such variations by adjustments known in the art, such as adjustment of total gas flow, gas velocity, deposition times etc., to achieve the coating properties of the present invention.

If not otherwise indicated, in the examples herein, the reactor was filled with inserts up to about its full capacity, whereby sample inserts to be investigated were placed at three different radial positions on the trays from the central inlet pipe (positions: center (C), middle (M), periphery(P)) and on six different tray levels within the height of the reactor. The remaining positions on the trays were filled with “scrap” inserts to simulate, as close as possible, full scale deposition conditions and volume usage within the reactor.

If not otherwise indicated, in the examples herein, measured values indicated for a sample, such as layer thicknesses, texture coefficients, A and Z adhesion etc., represent the average of 18 samples taken from the 18 various positions within the reactor, as described above.

### Blasting

If blasting of a deposited coating was performed, it was done on the rake faces of the inserts. Dry Blasting (“TS”) was carried out with ZrO₂ round media with a diameter of 70-120 μm, a blasting pressure of 5 bar (injector pressor=1.8 bar), and a blasting distance of 90 mm. Wet blasting (“TT”) was carried out with a blaster slurry of 20 vol-% Al₂O₃ in water (F240 micro grit), a blasting pressure of 2.8-3.8 bar (injector pressor=1.-2.0 bar), a blasting angle of 75°, and a blasing distance of 94.5 mm.

### Crater Wear Test

The coated cutting tools were tested in C45E steel using the following cutting data:
Cutting speed v_{c}: 270 m/min
Cutting feed, f: 0.32 mm/revolution
Depth of cut, aₚ: 2.5 mm
Insert style: WNMG080412
(no cutting fluid)

One cutting edge per cutting tool was evaluated. In analyzing the crater wear, the area of exposed substrate was measured, using a light optical microscope. The lifetime of the tool was considered to be reached when the wear crater formed by the flowing chips breaks through/reaches the secondary cutting edge. The wear of each cutting tool was evaluated after 3 minutes cutting in the light optical microscope. The cutting process was then continued with a measurement after each 3 minutes run, until the tool life criterion was reached. Beside crater wear, flank wear was also observed.

### Toughness Test—Edge Line Damage (ELD)

The coated cutting tools (blasted or unblasted) were tested in an intermitted turning operation in C45E steel using the following cutting data:
Cutting speed v_{c}: 200 m/min
Cutting feed, f: 0.2 mm/revolution
Depth of cut, aₚ: 2.64 mm
Insert style: WNMG080412

The work piece material consisted of C45E. The intermitted cutting process during this type of testing has shown to be critical for tool's lifetime. The end of tool life was assumed to be reached, if an edge-line damage (ELD) of 70% (criterion #1) or a wear VBₘₐₓ on the flank face of 0.3 mm (criterion #2) was reached or exceeded, whichever occurred earlier. Water miscible metal working fluid was used.

### EXAMPLES

### Substrates

In the present examples, substrates of cemented carbide with the cutting insert geometries ISO-type CNMA120412 and WNMG080412 were used. The cemented carbide composition was 86.11 wt. % WC, 5.48 wt. % Co, 3.52 wt. % TaC, 2.12 wt. % TiC, 2.33 wt. % NbC and 0.44 wt. % other carbides. The substrates have a Co binder enriched surface zone of about 20 μm from the substrate surface.

For the CVD depositions, inserts of the two different geometries CNMA120412 and WNMG080412 were coated in the same deposition run under the same conditions by placing at least one insert of geometry CNMA120412 and one insert of geometry WNMG080412 next to each other at the same radial and tray level positions within the CVD reactor. Due to its more simple geometry and flat surfaces, and thus, easier handling, the CNMA120408 inserts were used for coating analytics and measurements (including A and Z adhesion analyses), whereas the WNMG080412 inserts, which is a common turning tool insert geometry for steel machining, were used in cutting tests.

### Depositions

The coating sequence in the depositions of the examples herein was: TiN base layer/TiCN coating (MT-TiCN)/TiAICNO bonding layer/α-Al₂O₃ layer. An oxidation step was applied to the bonding layer prior to the deposition of the α-Al₂O₃ layer. In all inventive and comparative examples prepared herein, the TiN base layer, the TiAICNO bonding layer, the oxidation step and the α-Al₂O₃ layer were deposited and carried out, respectively, under the same process conditions to make the examples comparable with respect to variations of the single-layer or multi-layer TiCN coatings.

The process parameters for the depositions of the layers of inventive and comparative samples are given in table 1, and the TiCN coating sequences are given in table 3. The process steps and parameters for the depositions of the layers of reference sample 1246260 are given in table 2. The parameters measured on the samples (average of 18 inventive and comparative samples, respectively, distributed in the reactor, as described above) are given in table 4.

The TiN base layer was about 0.3-0.5 μm thick. The TiAICNO bonding layer had a thickness of about 1.0-1.5 μm. The α-Al₂O₃ layer had a thickness of about 5.5-6.5 μm. The thickness of the TiCN coating was in the range of about 7.5-11.0 μm.

The bonding layer consisted of multi-sublayer structure deposited in five coating steps BL-a to B-e. The deposition of the α-Al₂O₃ was carried out in two steps, Step 1 and Step 2.

### Adhesion Analyses

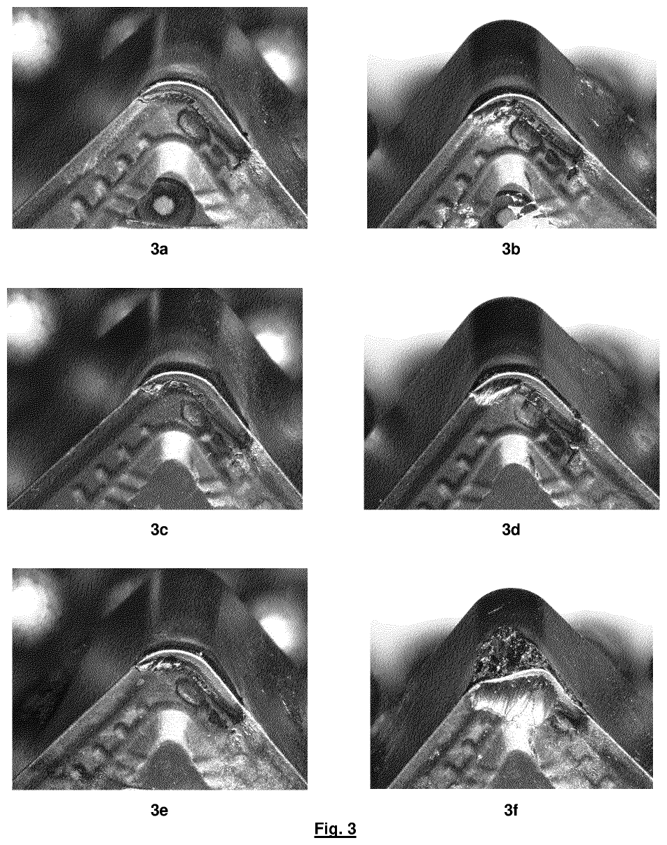

Average values for A and Z adhesion from the inventive and comparative samples (see tables 3 and 4) were determined and plotted over the number of multilayers (FIG. 2a; #-ML) and the texture coefficient TC (4 2 2) of the TiCN layer (FIG. 2b), respectively. In the dashed box in FIGS. 2a and 2b the mono-layer samples (#-ML=1) using TiCN-C and TiCN-D are marked. The results show that #-ML and TC (4 2 2) have only very little influence on Z adhesion, even for the mono-layer samples. However, a strong negative linear dependency of the A-adhesion over #-ML and a strong positive linear dependency of the A adhesion over TC (4 2 2) was observed. Both mono-layer examples show very weak A adhesion. The multi-sublayer samples within the #-ML and TC(4 2 2) ranges of the TiCN layer of the present invention show improved A adhesion and, at the same time, improved cutting properties.

TABLE 1
Process parameters and reaction gases during deposition for layers in inventive and comparative samples

| | Temp | Pressure | Time | H₂ | N₂ | TiCl₄ | CH₄ | CH₃CN | HCl | AlCl₃ | CO₂ | CO | H₂S | Total |
|---|---|---|---|---|---|---|---|---|---|---|---|---|---|---|
| Layer Type | [° C.] | [mbar] | [min] | [vol %] | [vol %] | [vol %] | [vol %] | [vol %] | [vol %] | [vol %] | [vol % | [vol %] | [vol %] | [l/min] |
| TiN (base layer) | 885 | 300 | 60 | 54.9 | 43.9 | 1.2 | — | — | — | — | — | — | — | 90.9 |
| TiCN-A (N type) | 885 | 70 | var. | 57.3 | 41.7 | 0.9 | — | 0.1 | — | — | — | — | — | 96.0 |
| TiCN-B (C type) | 885 | 70 | var. | 81.8 | 14.9 | 2.7 | — | 0.6 | — | — | — | — | — | 67.2 |
| TiCN-C (C type) | 885 | 55 | 320 | 87.8 | 8.8 | 2.7 | — | 0.7 | — | — | — | — | — | 113.9 |
| TiCN-D (C type) | 885 | 70 | 320 | 81.5 | 14.8 | 3.0 | — | 0.7 | — | — | — | — | — | 67.5 |
| TiCN-E (N type) | 885 | 70 | var. | 63.1 | 36.0 | 0.8 | — | 0.1 | — | — | — | — | — | 96.0 |
| TiCN-F (C type) | 885 | 70 | var. | 85.1 | 12.2 | 2.2 | — | 0.5 | — | — | — | — | — | 67.2 |
| BL-a | 1000 | 400 | 25 | 67.5 | 25.9 | 1.5 | — | 3.4 | 1.7 | — | — | — | — | 88.9 |
| BL-b | 1000 | 70 | 12 | 83.1 | 12.5 | 1.5 | 0.4 | — | 1.3 | — | — | 1.2 | — | 120.4 |
| BL-c | 1000 | 70 | 5 | 71.6 | 23.1 | 2.3 | 0.5 | — | — | 0.2 | — | 2.3 | — | 129.9 |
| BL-d | 1000 | 70 | 7 | 71.9 | 23.2 | 2.3 | — | — | — | 0.3 | — | 2.3 | — | 129.3 |
| BL-e | 1000 | 55 | 10 | 99.5 | — | — | — | — | — | 0.5 | — | — | — | 65.3 |
| Oxidation step | 1000 | 65 | 5 | 57.1 | 31.7 | — | — | — | — | — | 3.2 | 8.0 | — | 63.0 |
| α-Al₂O₃ (step 1) | 1000 | 65 | 30 | 93.2 | — | — | — | — | 1.4 | 1.4 | 2.7 | 1.3 | — | 74.0 |
| α-Al₂O₃ (step 2) | 1000 | 65 | 270 | 93.7 | — | — | — | — | 1.8 | 0.8 | 3.4 | — | 0.3 | 135.2 |

“BL” = Bonding Layer (multi-layer)

TABLE 2
Process steps and parameters for the layer deposition in reference sample (1246260 = prior art)

| | Temp | Pressure | Time | H₂ | N₂ | TlCl₄ | CH₃CN | CH₄ | HCl | AlCl₃ | CO₂ | CO | H₂S | Total |
|---|---|---|---|---|---|---|---|---|---|---|---|---|---|---|
| Layer Type | [° C.] | [mbar] | [min] | [vol %] | [vol %] | [vol %] | [vol %] | [vol %] | [vol %] | [vol % | [vol %] | [vol %] | [vol %] | [l/min] |
| TiN (base layer) | 900 | 160 | 51 | 59.4 | 39.6 | 1.0 | — | — | — | — | — | — | — | 88.4 |
| TiCN (step 1) | 900 | 75 | 90 | 71.5 | 25.7 | 2.2 | 0.6 | — | — | — | — | — | — | 69.9 |
| TiCN (step 2) | 900 | 70 | 240 | 89.4 | 7.9 | 2.0 | 0.7 | — | — | — | — | — | — | 76.1 |
| BL-1 | 1000 | 400 | 20 | 67.7 | 25.4 | 1.9 | — | 3.3 | 1.7 | — | — | — | — | 59.1 |
| BL-2 | 1000 | 70 | 4 | 84.1 | 12 | 1.5 | — | — | 1.2 | — | — | 1.2 | — | 83.2 |
| BL-3 | 1000 | 70 | 14 | 83.8 | 12 | 1.4 | 0.4 | — | 1.2 | — | — | 1.2 | — | 83.6 |
| BL-4 | 1000 | 70 | 6 | 65.3 | 28.1 | 2.7 | 0.6 | — | — | 0.5 | — | 2.8 | — | 71.2 |
| BL-5 | 1000 | 70 | 14 | 64.8 | 27.9 | 2.7 | — | — | — | 0.4 | — | 4.2 | — | 71.8 |
| BL-6 | 1000 | 45 | 10 | 99.5 | — | — | — | — | — | 0.5 | — | — | — | 62.8 |
| Oxidation step | 1000 | 55 | 6 | 57.1 | 31.7 | — | — | — | — | — | 3.2 | 8 | — | 63.0 |
| α-Al₂O₃ (step 1) | 1000 | 55 | 30 | 93 | — | — | — | — | 1.4 | 1.4 | 2.8 | 1.4 | — | 71.5 |
| α-Al₂O₃ (step 2) | 1000 | 75 | 320 | 95.2 | — | — | — | — | 0.9 | 0.8 | 2.8 | — | 0.3 | 130.3 |

“BL” = Bonding Layer (multi-layer)

TABLE 4
Measured Parameters

| | | TiCN | | | | | TiCN |
|---|---|---|---|---|---|---|---|
| | | Thickness | TiCN | Al₂O₃ | A | Z | # sublayers |
| # | Sample | [μm] | TC(4 2 2) | TC(0 0 12) | Adhesion | Adhesion | [#-ML] |
| 1 | WAG1719_V40 | 13.8 | 6.1 | 7.4 | 3.0 | 2.0 | 1 |
| 2 | 4WAG25 | 10.1 | 5.1 | 6.0 | 3.0 | 2.2 | 1 |
| 3 | 4WAG44 | 9.0 | 5.3 | 6.3 | 2.2 | 1.9 | 6 |
| 4 | 4WAG48 | 10.4 | 5.2 | 6.1 | 2.2 | 1.6 | 7 |
| 5 | 4WAG28.1 | 7.9 | 3.9 | 5.5 | 1.1 | 1.6 | 19 |
| 6 | 4WAG28.2 | 7.7 | 3.9 | 5.4 | 1.1 | 1.9 | 19 |
| 7 | 4WAG49 | 8.7 | 4.1 | 5.9 | 1.4 | 1.6 | 19 |
| 8 | 4WAG51 | 10.3 | 5.2 | 6.2 | 2.3 | 1.4 | 7 |
| 9 | 4WAG55 | 9.2 | 4.5 | 6.0 | 1.5 | 2.0 | 25 |
| 10 | 4WAG56 | 9.6 | 4.8 | 5.8 | 1.5 | 1.9 | 21 |
| 11 | 4WAG59 | 9.7 | 4.9 | 6.2 | 2.0 | 1.8 | 17 |
| 12 | 4WAG60 | 10.4 | 4.9 | 6.2 | 1.8 | 1.5 | 17 |

TABLE 3
TiCN coating sequences in inventive and comparative samples

| | | MT-TICN -,,X″ | | Depos. Time | | Total | Thickness |
|---|---|---|---|---|---|---|---|
| # | Sample # | Layer Sequence | | [min] | | layer no. | [μm] |
| 1 | WAG1719_V40 | 1x | C | 320 | | 1 | 13.8 |
| 2 | 4WAG25 | 1x | D | 320 | | 1 | 10.1 |
| 3 | 4WAG44 | 1x | B | 270 | | 6 | 9.0 |
| | | 2x | (A + B) | 2x | (7 + 25) | | |
| | | 1x | A | 32 | | | |
| 4 | 4WAG48 | 1x | B | 300 | | 7 | 10.4 |
| | | 3x | (A + B) | 3x | (7 + 25) | | |
| 5 | 4WAG28.1 | 9x | (B + A) | 9x | (25 + 7) | 19 | 7.9 |
| | | 1x | B | 32 | | | |
| 6 | 4WAG28.2 | 9x | (B + A) | 9x | (25 + 7) | 19 | 7.7 |
| | | 1x | B | 32 | | | |
| 7 | 4WAG49 | 9x | (B + A) | 9x | (30 + 10) | 19 | 8.7 |

| | | | | | | |
|---|---|---|---|---|---|---|
| | | 1x | B | 30 | | |
| 8 | 4WAG51 | 1x | B | 300 | 7 | 10.3 |

| | | | |
|---|---|---|---|
| 3x | (A + B) | 3x | (7 + 25) |

| | | | | | | |
|---|---|---|---|---|---|---|
| 9 | 4WAG55 | 1x | F | 25 | 25 | 9.2 |

| | | | |
|---|---|---|---|
| 12x | (E + F) | 12x | (7 + 25) |

| | | | | | | |
|---|---|---|---|---|---|---|
| 10 | 4WAG56 | 1x | B | 70 | 21 | 9.6 |

| | | | |
|---|---|---|---|
| 10x | (A + B) | 10x | (7 + 25) |

| | | | | | | |
|---|---|---|---|---|---|---|
| 11 | 4WAG59 | 1x | B | 134 | 17 | 9.7 |

| | | | |
|---|---|---|---|
| 8x | (A + B) | 8x | (7 + 25) |

| | | | | | | |
|---|---|---|---|---|---|---|
| 12 | 4WAG60 | 1x | B | 134 | 17 | 10.4 |

| | | | |
|---|---|---|---|
| 8x | (A + B) | 8x | (7 + 25) |
| 12x | (A + B) | | |

### Toughness Tests

Edge line toughness tests were carried out on a reference sample (1246260) and on two inventive samples (4AG51 and 4WAG5). Each sample was post-treated “T+TT”=dry blasting and subsequent wet blasting, as described above. All samples reached or exceeded a flank wear Bₘₐₓ of 0.3 mm (end of tool life criterion #2) long before an edge-line damage (EL) of 70% (end of tool life criterion #1) was reached. Therefore, ELD was determined for each sample after end of tool life de to flank wear. The results are shown in the following table 5and FIG. 5.

TABLE 5
Edge Line Toughness Test

| | # of cycles | flank wear | flank wear | ELD |
|---|---|---|---|---|
| | until | width after | width after | after |
| | VBmax >0.3 | 4 cycles | 6 cycles | end of |
| Sample # | mm | VBmax [mm] | VBmax [mm] | tool life |
| Ref. 1246260 | 4 | 0.36 | — | 35% |
| 4WAG51 | >7 | 0.15 | 0.26 | 31% |
| 4WAG55 | 6 | 0.22 | 0.34 | 29% |

### Crater Wear

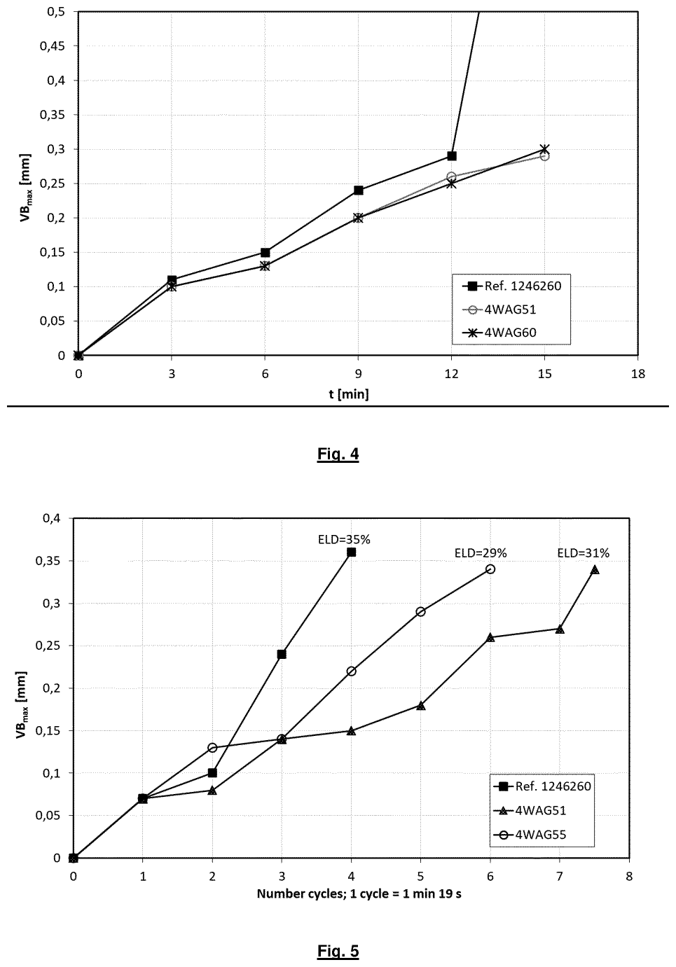

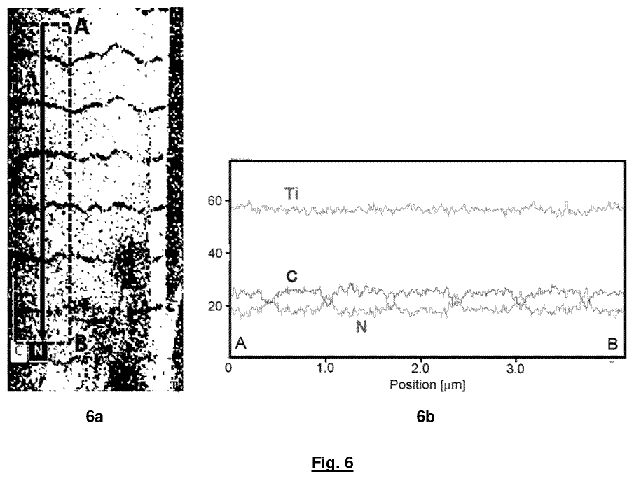

Inventive samples 4WAG51 and 4WAG60 and reference sample 1246260 were subjected to the crater wear test, as described above, (turning operation in C45E steel) for 12 min and 15 min, respectively. FIG. 3 shows the observed (LOM) wear of an inventive samples. (FIG. 3a=4WAG51, 12 min; 3b=4WAG51, 15 min, 3c=4WAG60, 12 min; 3d=4WAG60, 15 min; 3e=1246260, 12 min; 3f=1246260, 15 min). The results show similar crater wear of the inventive samples and the reference sample after 12 min, but after 15 min wear of the inventive samples was still acceptable, whereas the cutting edge and the rake and flank faces of the reference sample were almost completely destroyed. FIG. 4 shows the flank wear of the samples after each cycle of 3 min in the crater wear test.

1. A coated cutting tool for chip-forming metal machining consisting of a substrate and a multi-layered wear resistant hard coating, comprising:
a) a TiCN layer having a total thickness of from 2 μm to 20 μm, wherein the TiCN layer has a multi-sublayer structure of a total of p alternating C-type and N-type sublayers with p being an even or odd number in the range from 5 to 25, preferably wherein the C-type and N-type sublayers have different stoichiometries with respect to an atomic ratio of carbon and nitrogen, with the C-type TiCN sublayers having a C/N ratio in the range of 1.0≤C/N≤2.0, and the N-type TiCN sublayers having a C/N ratio in the range of 0.5≤C/N<1.0, and with a difference between the C/N ratio of adjacent C-type and N-type layers being ≥0.2, and wherein the TiCN layer has an overall fiber texture characterized by a texture coefficient TC (4 2 2) in the range from 3.0 to 5.5, the TC (4 2 2) being defined as follows:
$$T C ( 422 ) = \frac{I ( 422 )}{{I}_{0} ( 422 )} \cdot {( \frac{1}{n} \cdot {\sum }_{1}^{n} \frac{I ( hkl )}{{I}_{0} ( h k l )} )}^{- 1}$$
wherein
I(h k l)=XRD intensity of the (h k l) reflection
I₀(h k l)=standard intensity of the standard powder diffraction data according to lCDD's PDF-card no 01-071-6059
n=7=number of reflections used in the calculation, whereby the seven (h k l) reflections used are: (1 1 1), (2 0 0), (2 2 0), (3 1 1), (3 3 1), (4 2 0), and (4 2 2);
b) a single-layer or multi-sublayer oxygen containing Ti or Ti+Al compound bonding layer on top of the TiCN layer with a total thickness of from 0.5 μm to 3 μm; and
c) an α-Al₂O₃ layer on top of the bonding layer with a total thickness of from 2 μm to 15 μm, wherein the α-Al₂O₃ layer has an overall fiber texture characterized by a texture coefficient TC (0 0 12)>5, the TC (0 0 12) being defined as follows:
$$TC ( 0 \; 012 ) = \frac{I ( 0012 )}{{I}_{0} ( 0012 )} \cdot {( \frac{1}{n} \cdot {\sum }_{1}^{n} \frac{I ( hkl )}{{I}_{0} ( h k l )} )}^{- 1}$$
wherein
I(h k l)=XRD intensity of the (h k l) reflection
I₀(h k l)=standard intensity measured on the NIST standard powder SRM676a
n=8=number of reflections used in the calculation, whereby the eight (h k l) reflections used are: (1 0 4), (1 1 0), (1 1 3), (0 2 4), (1 1 6), (3 0 0), (0 0 12) and (0 1 14),
the standard intensities having the following values:

| | {h k l} | | | | | | | |
|---|---|---|---|---|---|---|---|---|
| | {1 0 4} | {1 1 0} | {1 1 3} | {0 2 4} | {1 1 6} | {3 0 0} | {0 0 12} | {0 1 14} |
| I₀ (h k l) | 87.93 | 37.68 | 100.00 | 45.76 | 92.43 | 53.93 | 2.05 | 5.16 |

2. The coated cutting tool of claim 1, wherein at least one base layer of TiN or TiC is deposited immediately on the substrate surface and underneath the TiCN layer, the base layer having a thickness in the range from 0.3 to 1.5 μm, or from 0.3 to 1.0 μm, or from 0.3 to 0.7 μm.

3. The coated cutting tool of claim 1, wherein the TiCN layer has an overall fiber texture characterized by a texture coefficient TC (4 2 2) in the range from 3.5 to 5.5 or from 4.0 to 5.3.

4. The coated cutting tool of claim 1, wherein in the multi-sublayer structure of the TiCN layer in a growth direction the first sublayer on top of the base layer and a final sublayer underneath the bonding layer are C-type layers.

5. The coated cutting tool of claim 1, wherein in the multi-sublayer structure of the TiCN layer each N-type sublayer has a thickness of less than 50%, or less than 40%, or less than 30% of each of the adjacent C-type sublayers.

6. The coated cutting tool of claim 1, wherein in the multi-sublayer structure of the TiCN layer each N-type sublayer has a thickness of at least 0.05 μm, or at least 0.1 μm, or at least 0.2 μm.

7. The coated cutting tool of claim 1, wherein in the multi-sublayer structure of the TiCN layer in the growth direction the first C-type sublayer has a thickness in the range from 2 to 15 μm, and subsequent C-type sublayers have a thickness in the range from 0.5 to 4 μm, or all C-type sublayers have a thickness in the range from 0.5 to 4 μm.

8. The coated cutting tool of claim 1, wherein the Ti or Ti+Al compound bonding layer has a multi-sublayer structure and a total composition of TiCNO or TiAlCNO.

9. The coated cutting tool of claim 1, wherein the substrate consists of cemented carbide, cermet, ceramics, steel or cubic boron nitride, preferably of cemented carbide.

10. The coated cutting tool of claim 1, wherein the layers of the hard coating are deposited by chemical vapour deposition (CVD), the TiCN is a MT-TiCN layer deposited by MT-CVD at a reaction temperature in the range from 600° C. to 900° C., and/or the Ti or Ti+Al compound bonding layer is deposited by HT-CVD at a reaction temperature in the range from 900° C. to 1200° C., and/or the α-Al₂O₃ layer is deposited by HT-CVD at a reaction temperature in the range from 900° C. to 1200° C.

11. The use of the coated cutting tool of claim 1 for continuous and interrupted chip-forming machining of ISO P or ISO K steel materials, including turning operations.

12. A process for manufacturing of a coated cutting tool of claim 1, wherein the multi-layered wear resistant hard coating is deposited on the substrate by chemical vapour deposition (CVD), comprising the steps of:
deposition of the TiCN layer in a multi-sublayer structure of a total of p alternating C-type and N-type sublayers with p being an even or odd number in the range from 5 to 20, by MT-CVD at a reaction temperature in the range from 600° C. to 900° C. from a process gas composition including at least TiCl₄, H₂, N₂ and CH₃CN and optionally HCl, to a total thickness of from 2 μm to 20 μm, wherein the C-type and N-type sublayers have different stoichiometries with respect to the atomic ratio of carbon and nitrogen, with the C-type TiCN sublayers having a C/N ratio in the range of 1.0≤C/N≤2.0, and the N-type TiCN sublayers having a C/N ratio in the range of 0.5≤C/N<1.0, and with the difference between the C/N ratio of adjacent C-type and N-type layers being ≥0.2, the C/N ratio being adjusted by the ratio of N₂/CH₃CN in the process gas composition;
deposition of the single-layer or multi-sublayer oxygen containing Ti or Ti+Al compound bonding layer on top of the TiCN layer to a total thickness of from 0.5 μm to 3 μm, by thermal HT-CVD or MT-CVD from a process gas composition including at least TiCl₄, H₂, N₂, CO and, if Al is present, AlCl₃ and optionally CH₄ and/or HCl;
carrying out an oxidation step to the bonding layer at a temperature in the range from 900-1200° C., a pressure in the range from 30 to 150 mbar, a time from 2-20 min, and in a gas atmosphere consisting of H₂, N₂, 1-10 vol. % CO₂ and 1-20 vol. % CO; and
deposition of an α-Al₂O₃ layer on top of the oxidation step treated bonding layer with a total thickness of from 2 μm to 15 μm, by HT-CVD at a reaction temperature in the range from 900° C. to 1200° C.

13. The process of claim 12, further comprising the step of deposition of at least one base layer of TiN or TiC immediately on the substrate surface to a base layer thickness in the range from 0.3 to 1.5 μm by thermal HT-CVD or MT-CVD from a process gas composition comprising at least TiCl₄, H₂ and N₂.

14. The process of claim 12, wherein the Ti or Ti+Al compound bonding layer is deposited by multiple subsequent deposition steps to obtain a multi-sublayer structure, wherein each deposition step is carried out by HT-CVD at a reaction temperature in the range from 900° C. to 1200° C.
